(19) United States
(12) Patent Application Publication
(10) Pub. No.: US 2025/0176433 A1
(43) Pub. Date: May 29, 2025

(54) VIBRATION DEVICE AND VIBRATION METHOD THEREOF

(71) Applicant: TDK Corporation, Tokyo (JP)

(72) Inventors: Noriaki SATO, Tokyo (JP); Takashi KATO, Tokyo (JP); Tetsuyuki TANIGUCHI, Tokyo (JP)

(73) Assignee: TDK Corporation, Tokyo (JP)

(21) Appl. No.: 18/940,032

(22) Filed: Nov. 7, 2024

(30) Foreign Application Priority Data
Nov. 27, 2023 (JP) 2023-199878

(51) Int. Cl. H10N 30/20; H02J 50/10; H04R 3/00; H04R 17/00

(52) U.S. Cl. CPC H10N 30/20; H02J 50/10; H04R 3/00; H04R 17/00

(57) ABSTRACT

In the IC card, the control circuit includes the first control unit for generating the audio vibration signal and the amplifier circuit for amplifying the audio vibration signal generated at the first control unit, and the drive signal amplified at the amplifier circuit is used as the drive signal for driving the piezoelectric element. Therefore, the vibration of the piezoelectric element exhibits a behavior according to the audio vibration signal. That is, the vibration of the piezoelectric element exhibits a continuous and smooth behavior in comparison with the behavior according to the square-pulse signal, and the vibration pattern of the piezoelectric element is increased in diversity.

### CROSS-REFERENCE TO RELATED APPLICATIONS

This application is based upon and claims the benefit of priority from Japanese Patent Application No. 2023-199878, filed on 27 Nov. 2023, the entire content of which is incorporated herein by reference.

### TECHNICAL FIELD

The present disclosure relates to a vibration device and a vibration method of the vibration device.

### BACKGROUND

Japanese Unexamined Patent Application Publication No. 2014-132404 discloses, as a kind of vibration device, a contactless IC card provided with a vibration mechanism. As a source of vibration in the vibration mechanism, a piezoelectric element or a motor for vibration is used.

### SUMMARY

The present inventors have studied a vibration pattern of the vibration device, and as a result, have newly found a technique for increasing diversity of the vibration pattern.

According to aspects of the present disclosure, a vibration device and a vibration method thereof increasing diversity of the vibration pattern are provided.

According to one aspect of the present disclosure, there is provided a vibration device including a power receiving unit configured to receive supply of contactless power from a power supply device, a control unit configured to generate a drive signal according to the power received at the power receiving unit, and a piezoelectric vibration element vibrating according to the drive signal generated at the control unit. The control unit includes a first control unit configured to generate an audio vibration signal and a second control unit configured to generate the drive signal by amplifying the audio vibration signal generated at the first control unit.

According to one aspect of the present disclosure, there is provided a vibration method of a vibration device including a power receiving unit configured to receive supply of contactless power from a power supply device, a control unit configured to generate a drive signal according to the power received at the power receiving unit and including a first control unit configured to generate an audio vibration signal and a second control unit configured to amplify the audio vibration signal generated at the first control unit to generate the drive signal, and a piezoelectric vibration element, the piezoelectric vibration element vibrates according to the drive signal generated at the second control unit of the control unit.

In the above vibration device and the vibration method thereof, the control unit includes the first control unit for generating the audio vibration signal and the second control unit for amplifying the audio vibration signal generated at the first control unit, and the signal amplified at the second control unit is used as the drive signal for driving the piezoelectric vibration element, whereby the vibration according to the audio vibration signal can be realized and the vibration pattern of the piezoelectric vibration element can be increased in diversity.

### BRIEF DESCRIPTION OF THE DRAWINGS

FIG. 1 is a schematic perspective view showing an IC card according to one embodiment.

FIG. 2 shows how a user holds the IC card shown in FIG. 1 over a reader-writer.

FIG. 3 is an exploded perspective view showing a lamination structure of the IC card in FIG. 1.

FIG. 4 shows a vibration circuit of the IC card in FIG. 1.

FIG. 5 shows another embodiment of the vibration circuit of the IC card.

FIG. 6 shows another embodiment of the vibration circuit of the IC card.

### DETAILED DESCRIPTION

Hereinafter, embodiments of the present disclosure will be described in detail with reference to the accompanying drawings. In the description, the same reference numerals are used for the same elements or elements having the same functions, and redundant description will be omitted.

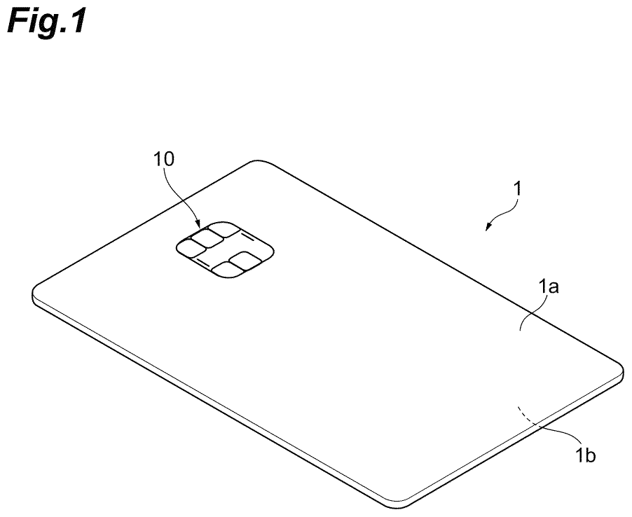

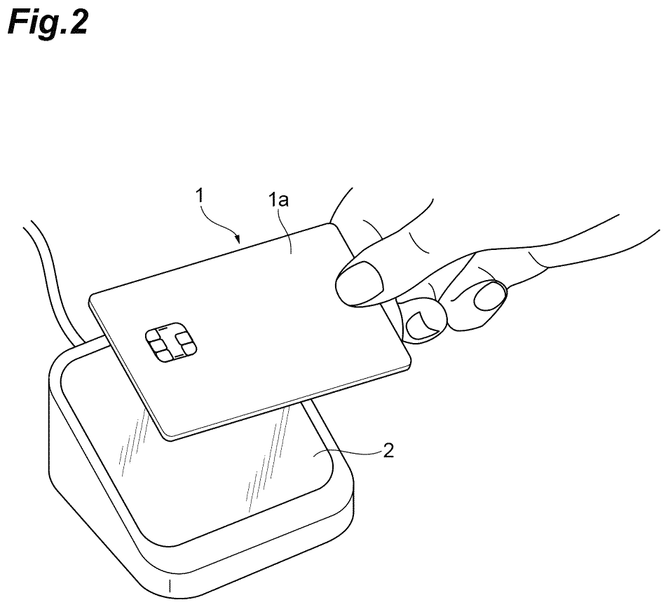

As a kind of the vibration device, an IC card shown in FIG. 1 is described for an example. The IC card 1 includes an embedded IC module 10 for performing arithmetic processing. The IC card 1 according to the present embodiment is a contactless type, and includes an antenna coil 16 to be described later is embedded. As shown in FIG. 2, the IC module 10 is held over a reader-writer 2 (i.e., kept away from the reader-writer 2 by a predetermined distance), which is a kind of power supply, so that the IC module 10 is supplied with contactless power from the reader-writer 2 and communicates with the reader-writer 2. The “contactless power supply” in the present specification includes contactless communication such as near field communication (NFC) in addition to power transmission.

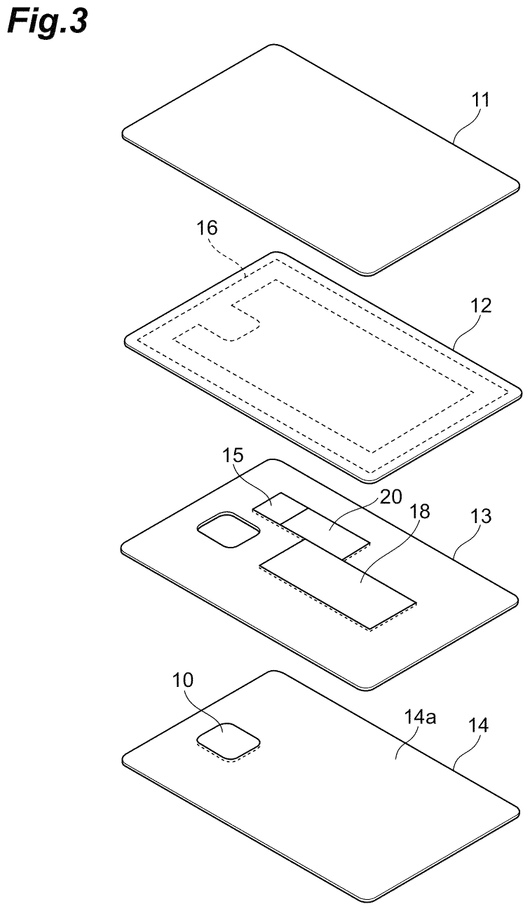

The IC card 1 has a plate-like outer shape, and has a front surface 1a and a back surface 1b. The IC module 10 is exposed in the front surface 1a. The IC card 1 has a lamination structure as shown in FIG. 3, which is laminated in the order of a plastic plate 11, an antenna sheet 12, a base substance 13, and a metal plate 14 from the back surface 1b side. Each interlayer of the IC card 1 is adhered by a known adhesion layer (for example, a double-sided adhesive tape, an adhesive material layer) which is not shown.

The plastic plate 11 is made of resin material that does not hinder the magnetic flux. The surface of the plastic plate 11 configures the back surface 1b of the IC card 1. The metal plate 14 is made of metal material such as stainless or titanium. The surface of the metal plate 14 configures the front surface 1a of the IC card 1. The IC module 10 is inleted in a part of a region of the metal plate 14.

The base substance 13 is a film made of insulating resin material, and can be configured by acrylic, for example. In the base substance 13, a voltage regulator 15, a piezoelectric element 18 and a control circuit 20 are mounted. The piezoelectric element 18 is a kind of piezoelectric vibration element, and the piezoelectric vibration element may be composed of a piezoelectric element, or may be composed of a piezoelectric element and a vibrating plate. The vibrating plate may be a plate made of resin or a plate made of metal. In the present embodiment, the piezoelectric element 18 is set in a through hole provided in the base substance 13 and is adhered to a rear surface 14a of the metal plate 14. The adhesive fixing of the piezoelectric element 18 to the metal plate 14 results in the transmission of displacement and vibration of the piezoelectric element 18 to the metal plate 14. That is, the vibration generated in the piezoelectric element 18 is transmitted from the inside to the surface of the IC card 1, and is directly sensed by the user of the IC card 1. The IC card 1 may vibrate wholly or locally in a part of the surface.

The antenna sheet 12 is made of insulating resin material or magnetic material. The antenna sheet 12 is provided with the antenna coil 16 including a coil pattern wound along the outer edge of the antenna sheet 12. The antenna coil 16 is electrically connected to the voltage regulator 15 of the base substance 13. The antenna coil 16 is magnetically connected to a coil in the IC module 10 of the metal plate 14.

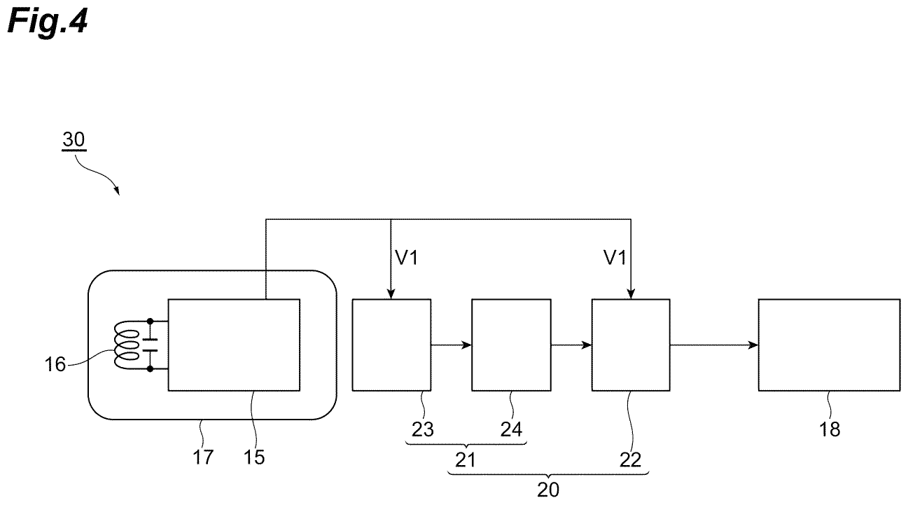

The IC card 1 has a vibration circuit 30. The configuration of the vibration circuit 30 is shown in FIG. 4. The vibration circuit 30 includes a power receiving unit 17 receiving contactless power supply from the reader-writer 2, a control circuit 20 (a control unit) generating a drive signal according to power received at the power receiving unit 17, and a piezoelectric element 18 vibrating according to the drive signal generated at the control circuit 20.

The power receiving unit 17 includes the voltage regulator 15 and the antenna coil 16. The power receiving unit 17 receives contactless power supply from the reader-writer 2 and outputs a drive voltage to drive the control circuit 20. The control circuit 20 includes a first control unit 21 and an amplifier circuit 22 (second control unit). In the present embodiment, the first control unit 21 is configured to include a microcomputer 23 (signal generation unit) that generates a square-pulse signal and a RC filter 24 (filter unit) that convert the square-pulse signal generated by the microcomputer 23 to an analog signal. Therefore, the first control unit outputs an audio vibration signal obtained by analog-converting the square-pulse signal. A drive voltage V1 is applied to each of the microcomputer 23 and the amplifier circuit 22 of the first control unit 21 from the power receiving unit 17. The value of the drive voltage V1 applied to the microcomputer 23 and the amplifier circuit 22 of the first control unit 21 is the same (+5V as an example). The audio vibration signal generated at the first control unit 21 is amplified (boosted) at the amplifier circuit 22, and the amplified drive signal is sent to the piezoelectric element 18. The piezoelectric element 18 vibrates according to the drive signal sent from the control circuit 20.

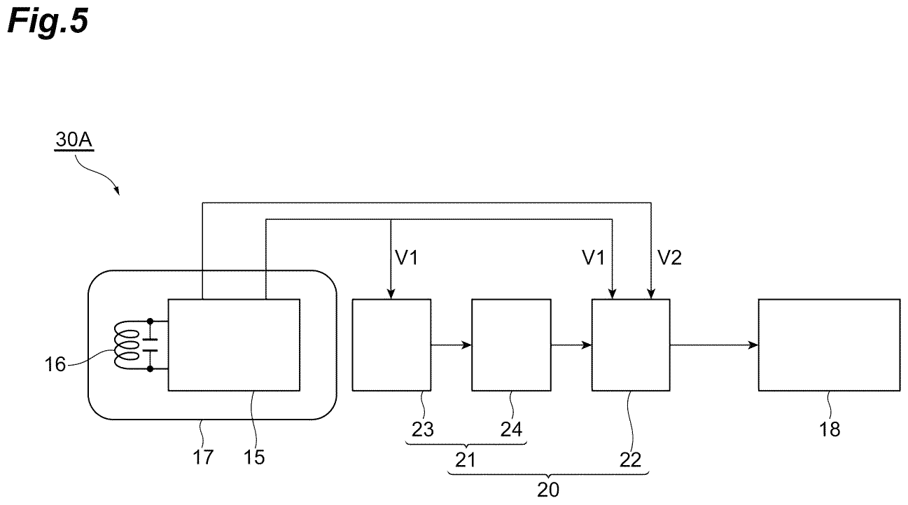

A power supply for use in the amplifier circuit 22 may not be a single power supply common to the power supply used in the microcomputer 23. For example, a high voltage V2 (i.e., V2>V1) output from the diode bridge in the power receiving unit 17 may be applied to the amplifier circuit 22 as the vibration circuit 30A shown in FIG. 5.

The first control unit 21 may not output an analog audio vibration signal but a digital audio vibration signal. The digital audio vibration signal output from the first control unit 21 may be subjected to analog demodulation and amplification in the amplifier circuit 22 including a DA converter.

In the IC card 1, the control circuit 20 includes the first control unit 21 for generating the audio vibration signal and the amplifier circuit 22 for amplifying the audio vibration signal generated at the first control unit 21, and the drive signal amplified at the amplifier circuit 22 is used as the drive signal for driving the piezoelectric element 18. Therefore, the vibration of the piezoelectric element 18 exhibits a behavior according to the audio vibration signal. That is, the vibration of the piezoelectric element 18 exhibits a continuous and smooth behavior in comparison with the behavior according to the square-pulse signal, and the vibration pattern of the piezoelectric element 18 is increased in diversity.

The square-pulse signal generated at the microcomputer 23 of the first control unit 21 may be a uniform pulse width signal or a pulse width modulated signal (i.e., a PWM signal). By generating the PWM signal at the microcomputer 21, the vibration of the piezoelectric element 18 which vibrates according to the drive signal of the control circuit 20 is modulated, whereby the piezoelectric element 18 can play the desired sound.

The first control unit 21 can generate the audio vibration signal related to music as a sound source (DSP sound source), and the piezoelectric element 18 can play a music.

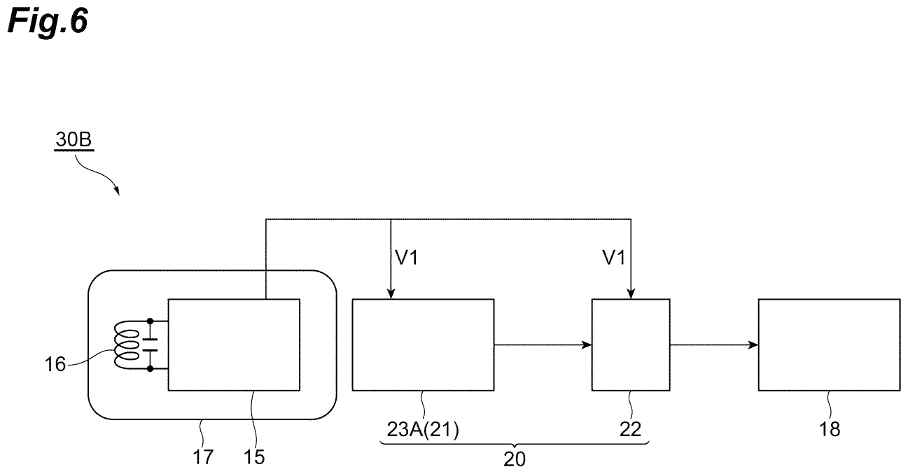

The first control unit 21 may be a combination of the microcomputer 23 and the RC filter 24 as described above, or the first control unit 21 can be replaced by the microcomputer 23A capable of directly outputting the audio vibration signal as in the vibration circuit 30B shown in FIG. 6.

The microcomputer 23A as the first control unit 21 may output a digital audio vibration signal. The digital audio vibration signal output from the microcomputer 23A may be subjected to analog demodulation and amplification in the amplifier circuit 22 including a DA converter.

The present disclosure is not limited to the above embodiments and may be variously modified. For example, the first control unit is not limited to a microcomputer, but may be an IC chip such as a timer IC. The vibration device is not limited to a form of a card, and may be a form of a small object or the like (i.e., fashion item, gadget, accessory, etc.). The power supply device is not limited to a reader-writer, and may be a payment terminal or the like.

What is claimed is:

1. A vibration device comprising:
a power receiving unit configured to receive supply of contactless power from a power supply device;
a control unit configured to generate a drive signal according to the power received at the power receiving unit; and
a piezoelectric vibration element vibrating according to the drive signal generated at the control unit,
wherein the control unit includes a first control unit configured to generate an audio vibration signal and a second control unit configured to generate the drive signal by amplifying the audio vibration signal generated at the first control unit.

2. The vibration device according to claim 1, wherein the first control unit includes a signal generation unit configured to generate a square-pulse signal and a filter unit configured to convert the square-pulse signal generated at the signal generation unit to an analog signal.

3. The vibration device according to claim 2, wherein the square-pulse signal generated at the signal generation unit of the first control unit is a PWM signal.

4. The vibration device according to claim 1, wherein the vibration device is an IC card.

5. A vibration method of a vibration device comprising a power receiving unit configured to receive supply of contactless power from a power supply device, a control unit configured to generate a drive signal according to the power received at the power receiving unit and including a first control unit configured to generate an audio vibration signal and a second control unit configured to amplify the audio vibration signal generated at the first control unit to generate the drive signal, and a piezoelectric vibration element,
wherein the piezoelectric vibration element vibrates according to the drive signal generated at the second control unit of the control unit.
